(19) United States
(12) Patent Application Publication
(10) Pub. No.: US 2001/0023118 A1
(43) Pub. Date: Sep. 20, 2001

(54) Customization of an integrated circuit in packaged form

(76) Inventors: John MacPherson, Fremont, CA (US); Ron Thomas, Salinas, CA (US); Alan H. Huggins, Gilroy, CA (US)

Correspondence Address: Tom Chen, Skjerven Morrill MacPherson LLP, Suite 700, 25 Metro Drive, San Jose, CA, 95110, US

(21) Appl. No.: 09/863,577

(22) Filed: May 23, 2001

Related U.S. Application Data
(63) Continuation-in-part of application No. 09/483,413, filed on Jan. 14, 2000.

(51) Int. Cl. H01L 21/20

(52) U.S. Cl. 438/584

(57) ABSTRACT

An unprogrammed die is attached to a die package, and bond wires are attached between the die and lead fingers on the die package. A cavity in the die package allows the die to be configured, such as with a laser. The die is then tested and, if needed, etched to ensure the desired configuration. The die package is sealed, such as with a filler material or a lid to protect the configured die and bond wires. In one embodiment, the die and bond wires are fully exposed through the cavity. In another embodiment, only a minority portion of the bona wires are exposed through the cavity. The cavity can be formed either prior to or after attaching the die and bond wires to the die package.

### BACKGROUND OF THE INVENTION

1. Field of the Invention

This invention relates to the manufacture of semiconductor devices, and more particularly, to the process of customizing an integrated circuit while in packaged form.

2. Discussion of the Related Art

Application-Specific Integrated Circuits, or ASICs, provide a cost-effective way of implementing a large number of digital logic circuits to perform a particular function. There are several types of ASICs which are available, depending on size, power, and programmability requirements, and volume of devices used. Fully custom devices offer the lowest cost and least amount of power consumption, but are only economical in very large quantities because of the costs of a custom mask set and the long engineering design time. Semi-custom devices such as gate arrays require a smaller number of custom masks and less design time as compared to fully custom devices, but have a larger die size, cost more to produce, and are typically used when needed quantities are not quite as large. Similarities exist in custom and semi-custom devices in that both have relatively long lead times to produce prototypes, and the designs are expensive and time consuming to change. As ASICs increase in circuit complexity, the likelihood of design errors in engineering prototypes increases, thus increasing the number of iterations required to obtain a design that is commercially practical. More complex ASIC designs will also require increasing the number of metallization layers, which define the custom circuit pattern, from the 2 or 3 layers used at present to 5 or more layers. Fabricating each layer of metallization requires two different masks (one for the metallization layer itself, and another for the pattern which connects the metallization layer to the one underlying it). These additional layers increase both the Non-Recurring Expense (“NRE”) of the ASIC as well as the lead time to obtain prototypes, which can typically run between 4 and 8 weeks. Compounding the preceding considerations is that product life cycles continue to decrease. This business reality complicates the problems facing ASIC design, debug, and development.

Non-custom programmable devices, such as programmable array logic (PALs), field-programmable gate arrays (FPGAs), and programmable logic devices (PLDs) can be substituted for ASICs. They are fabricated as unprogrammed “blanks” which are electronically programmed by the end user as packaged units or after installation onto a circuit board. The programmability of these non-custom devices dramatically shortens the lead time for developing a prototype ASIC design. Since no custom masks are required, the NRE costs and time to iterate designs are substantially reduced, requiring hours rather than the several weeks required for an ASIC. Consequently, electronically creating an ASIC by merely programming a standard IC appears highly desirable in comparison with physically manufacturing an ASIC. However, these programmable devices have the drawback of requiring a relatively large amount of die area dedicated to circuitry to perform the programming and to signal paths to provide flexibility in routing. The larger die area causes the devices to be more expensive to fabricate, increasing the unit cost. Moreover, such ICs cannot, in general, provide a circuit density and/or circuit performance comparable to that readily obtainable using ASICs. While prototypes can be produced quickly and design development accelerated using these devices, they are less desirable for designs which are to be fabricated in large quantities, require high performance, or are sensitive to power consumption.

Devices which are programmed through the use of disconnectable fuses, rather than electronically, offer some of the virtues and some of the drawbacks found in both programmable and semi-custom devices. Commonly used fuse-programmable devices have fuses that are disconnected through the use of a laser, focused ion beam, or other radiant energy beam device (hereinafter referred to as a “laser”). For these devices, dice are prepared by fabricating wafers nearly to completion and then storing them in preparation for configuration. A laser is used to disconnect the fuses to perform the programming, and the final fabrication steps are completed. Since the programmable element is a small section of interconnect material on one layer rather than a group of electronic circuit elements, these devices have a smaller amount of die area dedicated to a programming cell, and therefore have a smaller die size than the electronically programmable devices. Since the programming is performed without custom masks near the end of the wafer fabrication process, all of the custom mask expense and most of the lead time associated with custom and semi-custom devices is avoided.

Prototypes of laser-programmed circuits can be produced relatively quickly by using special assembly techniques after the conclusion of the fabrication steps. For plastic packages such as Plastic Leaded Chip Carrier (PLCC), Plastic Quad Flat Pack (PQFP), and Plastic Thin Quad Flat Pack (TQFP), among others, conventional assembly techniques generally consist of the following sequence of steps:

1. Saw the wafer into individual die and extract the die that are to be assembled into packages;

2. Deposit a small amount of die attach epoxy on the die pad of a lead frame, contained within a lead frame tape;

3. Place a die on the die attach epoxy and compress the die and the lead frame together to distribute the epoxy;

4. Bake the lead frame and die to cure the epoxy, bonding the die to the lead frame;

5. Attach bond wires between the bonding pads on the die and the lead fingers on the lead frame;

6. Place the lead frame tape within a mold, and inject a plastic packaging compound into the mold to encapsulate the die and a portion of the lead frame;

7. Separate the leads from the lead frame tape; and

8. Trim and form the leads.

Although these techniques can be used to produce packaged die inexpensively, a relatively large amount of capital investment is required to purchase the molds for the packages, and for the package-forming equipment. Conventional assembly services can be purchased from others, avoiding the equipment costs, but the lead time to complete the packaging is undesirably long (typically 10 to 20 days).

Alternatively, prototype packages can be prepared in advance by building packages without any die or bond wires, and then etching or otherwise removing the package material over the lead frame such that a cavity is formed, exposing the die pad and lead frame fingers. Since the packages can be constructed in advance of any prototype orders and stored until needed, the package formation process does not add to the overall lead time to deliver the prototype. With this material now prepared, a typical configuration and assembly process for a die includes the following basic steps:

1. Configure the die on a wafer using a laser;

2. Deposit a layer of silicon nitride or other passivation material;

3. Pattern and etch the nitride to expose the bond pads;

4. Test the die on the wafer to determine which die is functional;

5. Saw the wafer into individual dice and extract the working die;

6. Deposit a small amount of die attach epoxy on the die pad of the lead frame contained within a pre-formed cavity of a package;

7. Place a die on the die attach epoxy and compress the die and the package together to distribute the epoxy;

8. Bake the package and die to cure the epoxy, bonding the die to the lead frame;

9. Attach bond wires between the bonding pads on the die and the lead fingers on the package;

10. Seal the package by filling in the cavity with epoxy; and

11. Bake the package to cure the epoxy.

As mentioned, a desirable factor in the processing of prototypes is the ability to deliver them quickly. A prototype built according to the flow described above would typically take three to four days for passivation processing, three days for assembly, and another one to two days for all other processing combined (laser configuration, test, shipping, and handling), for a total time of seven to nine days lead time to deliver a prototype, or about one-half the time required to deliver a prototype using conventional assembly methods. While this contrasts favorably with the lead time to produce ASIC prototypes, it falls far short of the advantage offered by electronically programmable parts. Furthermore, the cost of producing an open-cavity package, the additional expense for low-volume, semi-manual assembly methods, and the scrap costs incurred for die that are not used on a wafer that is configured combine to make this method undesirably expensive for producing small quantities of parts. This again contrasts favorably with ASICs, but falls short of electronically programmable parts.

It is therefore desirable to have a structure and method for customizing a laser-programmable device that shortens the lead time required to produce configured, packaged parts, lowers the cost required to produce the parts, or both.

### SUMMARY OF THE INVENTION

According to the present invention, prior to die configuration (e.g., by blowing desired fuses with a laser), bond wires are attached between bonding pads on a die and lead fingers on a die package. Thus, individual die are assembled into packages and stored until ready for configuration. The die is then configured in the package and tested. If the die is not functional according to specifications, etching can be performed to remove any undesired residual connections and re-tested. If the die is functional as desired, the package is sealed and the device shipped. As a result, the lead time required to produce prototype parts of laser-programmable integrated circuits can be reduced, without increasing the processing or assembly costs. Further, the cost of manufacturing a laser-programmable integrated circuit can be reduced while still using conventional assembly techniques to package the circuits.

In one embodiment of the invention, a wafer is fabricated up to, but not including, the step of laser programming. The wafer is sawed up into dice. Open-cavity packages are produced in the proper size and pin count. The dice are assembled into the packages as unprogrammed blanks. A temporary protective lid is placed over the cavity and the parts are stored until needed. An entire wafer can be assembled into parts so that there is no scrap. When a prototype is needed, an unprogrammed packaged blank is placed into a laser mechanism and programmed by disconnecting the fuses in the usual manner. The die is removed from the laser and tested. If the die is not functional, it can be subjected to an etching process to complete the disconnection for any fuses with residual connections. The die is then sealed into the package by filling the cavity with an epoxy compound or other methods. After a final test for functionality and the application of an identification marking or label, the part is ready to ship to the customer.

In another embodiment of the invention, a wafer is again fabricated to the step of laser programming, sawed up into dice, and assembled into packages as unprogrammed blanks using standard techniques. The parts are then stored until needed. When a prototype is to be built, a part is taken out of storage, and a portion of the package is etched away to expose the die inside. The part is then placed into the laser mechanism and programmed, etched (if necessary), and encapsulated as described in the previous embodiment.

This invention will be more fully understood in light of the following detailed description taken together with the accompanying drawings.

### BRIEF DESCRIPTION OF THE DRAWINGS

FIG. 1A is a top plan view of an integrated circuit with laser alignment features contained in the scribe area between die for conventional die configuration;

FIG. 1B is a top plan view of an integrated circuit with laser alignment features contained within the die frame for use with the present invention;

FIG. 2A is a top plan view of a semiconductor package with a portion of the package removed to uncover the die paddle and the lead fingers, according to one embodiment of the present invention;

FIG. 2B is a side elevation cutaway view along line A-A′ of the semiconductor package of FIG. 2A;

FIG. 3 is a side elevation view of the semiconductor package of FIG. 2B with a die mounted on the lead frame and with bond wires attached from the lead fingers to the die;

FIG. 4 is a side elevation view of the semiconductor package of FIG. 3 after the cavity in the package has been filled to protect the die and bond wires;

FIG. 5 is a side elevation view of the semiconductor package of FIG. 3 that has been further processed to create a recess for mounting a lid;

FIG. 6 is a side elevation view of the semiconductor package of FIG. 5 after the cavity in the package has been sealed by attaching a lid;

FIG. 7A is a top plan view of a semiconductor package with a portion of the package removed to uncover the die paddle and the lead fingers, according to another embodiment of the present invention; and

FIG. 7B is a side elevation cutaway view along line B-B′ of the semiconductor package of FIG. 7A.

Use of the same reference numbers in different figures indicates similar or like elements.

### DETAILED DESCRIPTION

The present invention provides methods and structures to allow a die, which has already been sawed from a wafer, to be packaged and then configured (e.g., by laser programming). Upon successful configuration, the die is sealed in the package.

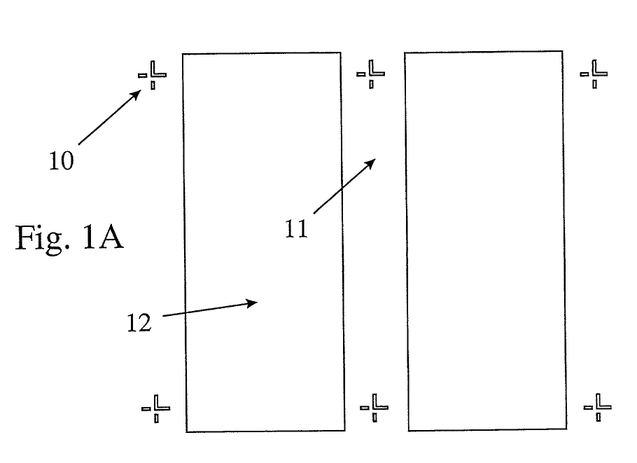

It is a common practice when performing an integrated circuit design layout to locate laser alignment features 10 in a scribe line 11 between a die 12, as shown in FIG. 1A. Since the laser programming is performed after the wafer has been sawed into individual dice according to the present invention, any alignment features along scribe line 11 will be destroyed. Therefore, it is a requirement during the design layout of any device that is to be configured according to the present invention that laser alignment features 10 be included within a die frame 13, preferentially located in the corners, as shown in FIG. 1B.

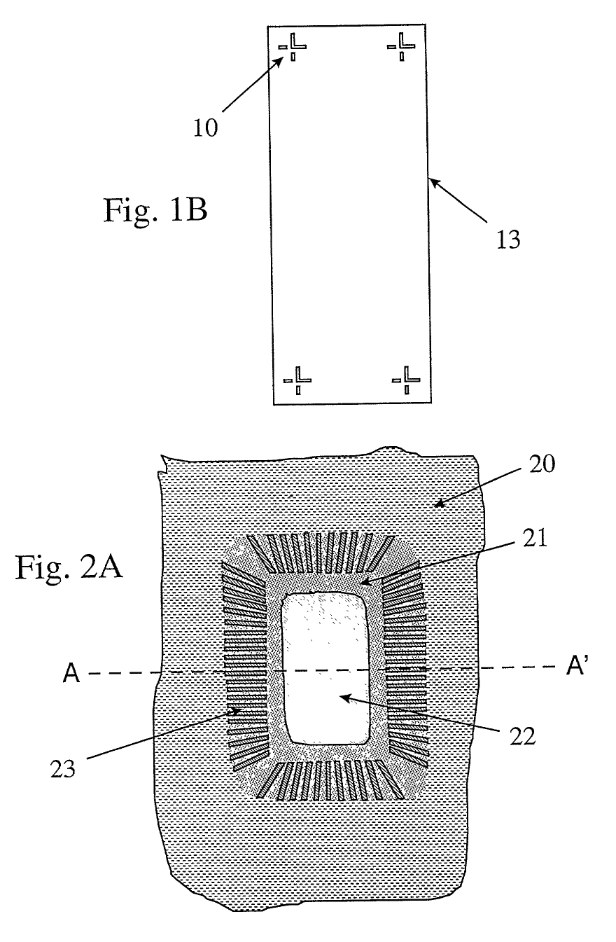

FIG. 2A shows a top view of a semiconductor package where a portion of a package 20 has been removed to create a cavity 21 and provide access to a die paddle 22 and lead fingers 23. Cavity 21 can be formed by mechanical means such as grinding, by wet or dry etching, or by a combination of these or other techniques. Alternately, the package can be a standard form or a custom construction which has a pre-formed opening in the top portion of the package when it is manufactured such that there is access to die paddle 22 and lead fingers 23.

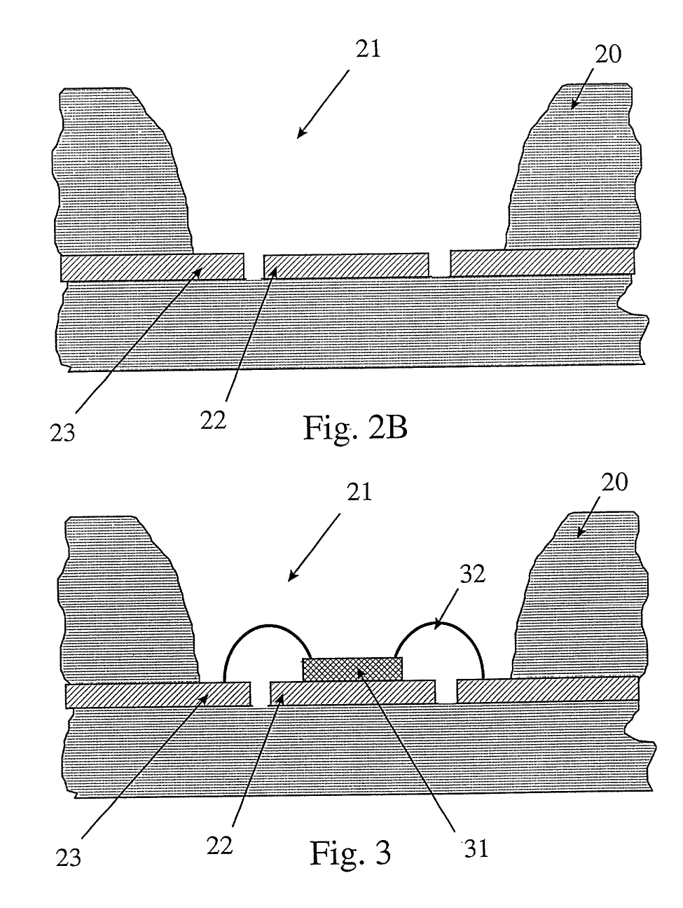

The cross-section of FIG. 2B is taken along the line A-A′ of FIG. 2A and shows package 20 with die paddle 22 and lead fingers 23 exposed. FIG. 3 shows a die 31 that has been attached to die paddle 22 and bond wires 32 that have been attached from connection points on die 31 to lead fingers 23 following conventional procedures. The part shown in FIG. 3 is now an unprogrammed “blank” that can be stored until needed. When a prototype order is received, the unprogrammed “blank” can be taken from storage, placed into a laser mechanism, and programmed by disconnecting the fuses in the usual manner. At the conclusion of the laser processing, the part is removed from the laser mechanism and tested, e.g., using a suitable integrated circuit electrical tester, to determine if the part is functional according to the desired programming pattern.

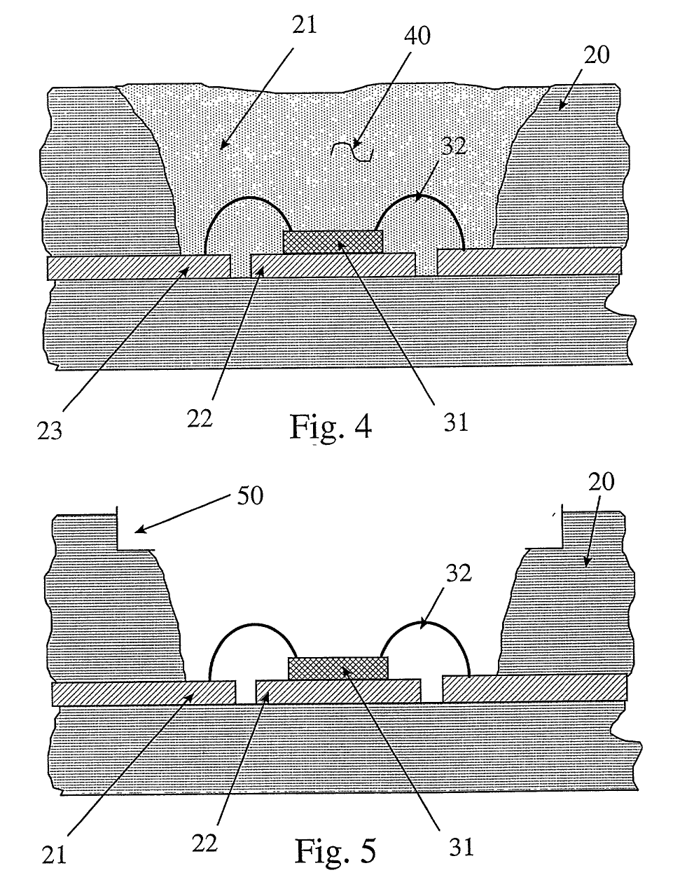

If the part is found to be functional, die 31 is sealed within package 20, as shown in FIG. 4, by filling cavity 21 with an encapsulate 40, which can be comprised of epoxy, resin, silicone, clay, polyimide, urethane polymer, rubber, plastic, acrylic, or other suitable materials, which preferentially have a low modulus (e.g., rigidity or hardness) and a low coefficient of linear thermal expansion (CTE) to minimize the mechanical stress between encapsulate 40 and the structures within the cavity. Encapsulate 40 may be in a compound with various filler materials which provide additional stress relief, or have an layer of material interposed between the encapsulate and the substrate for the purposes of stress relief or contamination isolation.

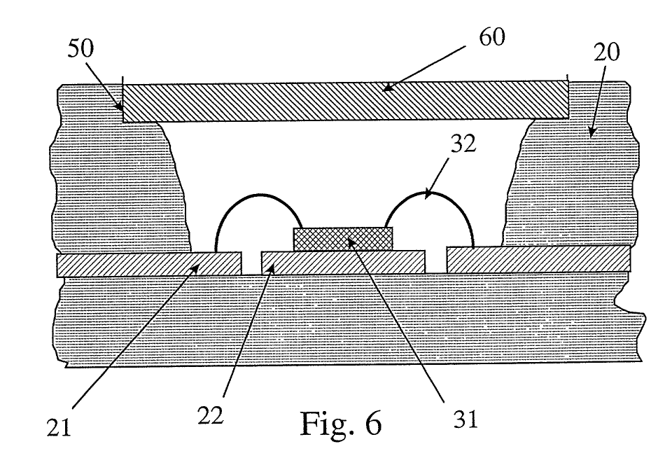

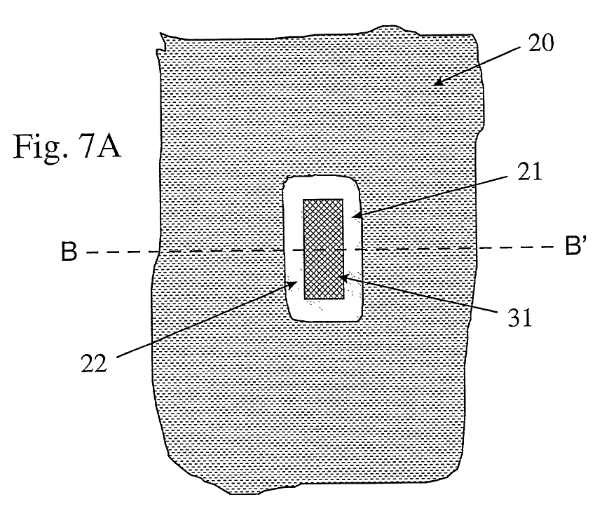

Alternatively, die 31 may be sealed within package 20 by attaching a lid to the package overlying the cavity. One technique for doing this, shown in FIGS. 5 and 6, is to provide a recess 50 in package 20 (shown in FIG. 5) to which a lid 60 (shown in FIG. 6) can be fitted and attached with glue or other adhesive methods. Alternatively, lid 60 can be glued, soldered, or otherwise bonded directly to the top surface of the package.

If the device is found not to be functional during the electrical testing, it can be further processed by etching the part using conventional wet or dry etching techniques to remove residual connections at the fuse sites. The part is then re-tested, and if found to be functional, sealed and marked as described above. Alternatively, the etching process can be an integral part of the fuse disconnection process, wherein the laser selects the fuses for disconnection by removing or altering an etch-resistant layer of material over the fuse in a manner which permits the fuse to be removed by conventional wet or dry etching techniques.

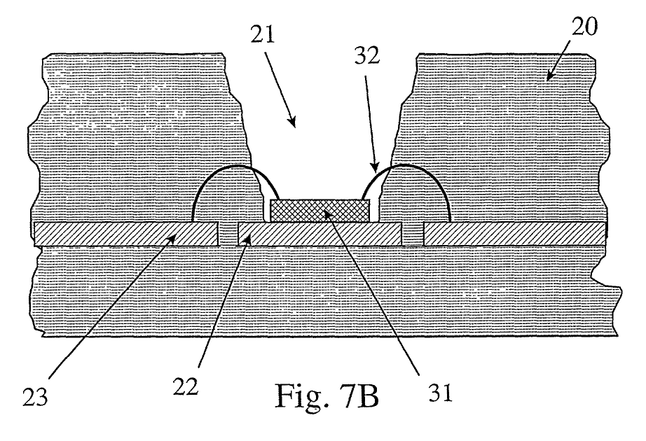

In another embodiment, an unprogrammed “blank” die is assembled in a package using conventional assembly techniques, and the die is later uncovered to permit configuration by a laser. As shown in FIG. 7A, a portion of package 20 is removed to form cavity 21, providing access to the top surface of the unprogrammed die 31. Cavity 21 can be formed over unprogrammed die 31 by mechanical means such as grinding, by wet or dry etching, or by a combination of these or other conventional etching techniques. The cross-section of FIG. 7B is taken along the line B-B′ of FIG. 7A and shows package 20 with die 31 exposed. Bond wires 32 (not shown in FIG. 7A for clarity) are mostly (e.g., more than 50%) contained within and protected by package 20 and are less susceptible to damage from handling or etching during the customization process. The part is now an unprogrammed “blank” which can be stored, and later customized as described in the previous embodiment. In addition to the protection of the bond wires, this embodiment offers a lower cost basis for assembly of the die in the package, since high-volume, automated processes replace the manual die attachment and wire bonding.

The above-described embodiments of the present invention are merely meant to be illustrative and not limiting. It will thus be obvious to those skilled in the art that various changes and modifications may be made without departing from this invention in its broader aspects. Therefore, the appended claims encompass all such changes and modifications as fall within the true spirit and scope of this invention.

We claim:

1. A method of customizing an integrated circuit, comprising:
attaching an unprogrammed die to a die package;
attaching bond wires from the unprogrammed die to lead fingers in the die package; and
configuring the die.

2. The method of claim 1, further comprising testing the die after the configuring.

3. The method of claim 1, further comprising sealing the die package after the configuring.

4. The method of claim 1, further comprising, prior to attaching the unprogrammed die, forming a cavity in the die package.

5. The method of claim 4, further comprising sealing the die package after the configuring.

6. The method of claim 5, wherein the sealing comprises filling the cavity.

7. The method of claim 5, wherein the sealing comprises attaching a lid over the cavity.

8. The method of claim 1, wherein the configuring is with a targeting energy beam.

9. The method of claim 8, wherein the targeting energy beam is a laser.

10. The method of claim 1, wherein the configuring comprises utilizing a targeting energy beam followed by utilizing an etching process.

11. A method of customizing an integrated circuit, comprising:
attaching an unprogrammed die to a die package;
attaching bond wires from the unprogrammed die to lead fingers in the die package;
encapsulating the die and the bond wires within the die package;
partially etching material overlying the die and the bond wires to expose the die and a portion of the bond wires; and
configuring the die.

12. The method of claim 11, wherein the partially etching exposes only a minority portion of the bond wires.

13. The method of claim 11, further comprising testing the die after the configuring.

14. The method of claim 11, further comprising sealing the die package after the configuring.

15. The method of claim 14, wherein the sealing comprises filling the cavity.

16. The method of claim 14, wherein the sealing comprises attaching a lid over the cavity.

17. The method of claim 11, wherein the configuring is with a targeting energy beam.

18. The method of claim 11, wherein the configuring comprises utilizing a targeting energy beam followed by utilizing an etching process.

19. A semiconductor structure, comprising:
a die package having a cavity;
an unprogrammed die attached to the die package, wherein the die is exposed through the cavity;
lead fingers coupled to the die package; and
bond wires attached between the unprogrammed die and the lead fingers, wherein the bond wires are at least partially exposed through the cavity.

20. The structure of claim 19, further comprising a bond pad coupled between the die package and the unprogrammed die.

21. The structure of claim 19, further comprising a filler enclosing the die and the bond wires, wherein the die has been configured.

22. The structure of claim 19, further comprising a lid attached to the die package over the cavity, wherein the die has been configured.

23. The structure of claim 19, wherein the bond wires are completely exposed through the cavity and the lead fingers are partially exposed through the cavity.

24. The structure of claim 19, wherein only a minority portion of the bond wires is exposed through the cavity.
